(19) United States
(12) Patent Application Publication
(10) Pub. No.: US 2016/0197302 A1
(43) Pub. Date: Jul. 7, 2016

(54) LIGHT EMITTING APPARATUS, LIGHTING APPARATUS, AND METHOD FOR MANUFACTURING LIGHT EMITTING APPARATUS

(71) Applicant: PANASONIC INTELLECTUAL PROPERTY MANAGEMENT CO., LTD., Osaka (JP)

(72) Inventors: Makoto SHIRAKAWA, Shiga (JP); Takaaki YOSHIHARA, Osaka (JP); Shingo HOUZUMI, Osaka (JP)

(73) Assignee: PANASONIC INTELLECTUAL PROPERTY MANAGEMENT CO., LTD., Osaka (JP)

(21) Appl. No.: 14/442,265

(22) PCT Filed: Nov. 11, 2013
(86) PCT No.: PCT/JP2013/006628

§ 371 Date: May 12, 2015

(30) Foreign Application Priority Data
Nov. 13, 2012 (JP) 2012-249364

(51) Int. Cl. H01L 51/52; H01L 51/56; H01L 51/00

(52) U.S. Cl. CPC H01L 51/525; H01L 51/0022; H01L 51/56

(57) ABSTRACT

The light emitting apparatus according to the present invention includes: a first substrate; a light emitting element supported on a surface of the first substrate; a second substrate spaced from and facing the surface of the first substrate; an adjusting layer supported on a surface of the second substrate facing the light emitting element; a barrier member provided between the first substrate and the second substrate so as to surround the light emitting element and the adjusting layer; and a sealing member filling a space surrounded by the first substrate, the second substrate, and the barrier member. The adjusting layer includes a surface which faces the first substrate and includes an adjusting surface. The adjusting layer is formed so that a distance between the adjusting surface and the first substrate becomes greater towards an outer edge of the adjusting layer than at a center part of the adjusting layer.

### TECHNICAL FIELD

The present invention relates to a light emitting apparatus including a light emitting element, a lighting apparatus including the light emitting apparatus, and a method for manufacturing the light emitting apparatus.

### BACKGROUND ART

Recently, a light emitting apparatus including a light emitting element has been used for a lighting panel and the like. The light emitting element, for example, is an organic electroluminescence element having a structure in which a light-transmissive first electrode, an organic layer including a light-emitting layer, and a second electrode are stacked in this order. Such a light emitting element is provided on a substrate (supporting substrate), and the light emitting element is isolated from the outside, and thereby a light emitting apparatus is obtained.

A method for sealing a light emitting element may be exemplified by a method including disposing a substrate (sealing substrate) so as to face a light emitting element on a supporting substrate, and filling a space between the supporting substrate and the sealing substrate with a sealing member made of an insulating adhesive or the like (see Patent Literature 1). When such a sealing member is used, a sealing member 27 is disposed between a supporting substrate 22 bearing a light emitting layer 24 and a sealing substrate 23 as shown in FIG. 6, and a distance between the supporting substrate 22 and the sealing substrate 23 is decreased to spread the sealing member 27 between the supporting substrate 22 and the sealing substrate 23, and thereby the light emitting element 24 can be easily enclosed. However, in this case, the sealing member 27 is apt to disadvantageously leak out from the space between the supporting substrate 22 and the sealing substrates 23.

In view of this, there has been proposed providing a barrier member 26 between the supporting substrate 22 and the sealing substrate 23 so as to surround the light emitting element 24 to dam the sealing member 27 by the barrier member 26.

### CITATION LIST

### Patent Literature

Patent Literature 1: JP 2010-198980 A

### SUMMARY OF INVENTION

### Technical Problem

However, when the sealing member is spread between the supporting substrate and the sealing substrate, the sealing member applies a strong stress to the barrier member, and this may cause deformation and breakage of the barrier member. Hence, yield of a light emitting apparatus becomes poor.

In the light of the above, an object of the present invention is to provide a light emitting apparatus capable of providing easy sealing of a light emitting element and being manufactured with high yield, a lighting apparatus including the light emitting apparatus, and a method for manufacturing the light emitting apparatus.

### Solution to Problem

The light emitting apparatus according to the first aspect of the present invention includes:
a first substrate;
a light emitting element supported on a surface of the first substrate;
a second substrate spaced from and facing the surface of the first substrate;
an adjusting layer (spaced distance change layer) supported on a surface of the second substrate facing the light emitting element;
a barrier member provided between the first substrate and the second substrate so as to surround the light emitting element and the adjusting layer; and
a sealing member filling a space surrounded by the first substrate, the second substrate, and the barrier member,
the adjusting layer including a surface which faces the first substrate and includes an adjusting surface (spaced distance change surface),
the adjusting layer being formed so that a distance between the adjusting surface and the first substrate becomes greater towards an outer edge of the adjusting layer than at a center part of the adjusting layer.

In the second aspect of the present invention, the adjusting surface is designed as a lateral surface of a conical solid or a lateral surface of a frustum.

For example, in the second aspect of the present invention realized in combination with the first aspect, the adjusting surface is a curved surface designed as a surface of a circular frustum formed so as to surround the center part of the adjusting layer.

In the third aspect of the present invention realized in combination with the first or second aspect, the adjusting surface is formed so that, with regard to any section of the light emitting apparatus containing a central axis of the space, a percentage of a distance from an outer edge of the adjusting surface to the barrier member to a distance from the central axis to the barrier member is equal to or less than 50%.

In the fourth aspect of the present invention, the space is elongated in a direction along the surface of the second substrate; and the adjusting surface is formed so that a region enclosed by any contour line on the adjusting surface on the basis of the surface of the second substrate is elongated in the direction.

In the fifth aspect of the present invention realized in combination with any one of the first to third aspects, the surface of the adjusting layer includes a flat surface which is closer to the outer edge of the adjusting layer than the adjusting surface is.

In the sixth aspect of the present invention realized in combination with any one of the first to fifth aspects, a thickness of the adjusting layer at the outer edge thereof is a half or less of a thickness of the adjusting layer at the center part thereof.

In the seventh aspect of the present invention realized in combination with any one of the first to sixth aspects, the adjusting layer is made of resin.

In the eighth aspect of the present invention realized in combination with any one of the first to seventh aspects, each of the first substrate, the second substrate, and the adjusting layer is light transmissive.

In the ninth aspect of the present invention, the adjusting layer is formed by printing.

The lighting apparatus according to the tenth aspect of the present invention includes the light emitting apparatus according to any one of the first to ninth aspects.

The method for manufacturing a light emitting apparatus according to the eleventh aspect of the present invention is a method for manufacturing the light emitting apparatus according to any one of the first to ninth aspects. The method includes: providing the light emitting element and the barrier member on the surface of the first substrate; providing the adjusting layer on the surface of the second substrate; disposing the first substrate and the second substrate so that the surface of the first substrate and the surface of the second substrate face each other; and disposing a sealing member between the light emitting element and the adjusting layer, and spreading the sealing member between the first substrate and the second substrate by pressing the sealing member by the adjusting layer while relatively moving the first substrate close to the second substrate until the barrier member comes into contact with the second substrate.

### Advantageous Effects of Invention

According to the present invention, the light emitting element is easily enclosed by spreading the sealing member between the first substrate and the second substrate, and the distance between the adjusting surface and the first substrate becomes greater towards the outer edge. Therefore, a stress applied to the barrier member by the sealing member is reduced, and thereby deformation and breakage of the barrier member can be suppressed.

### BRIEF DESCRIPTION OF DRAWINGS

FIG. 1A relates to the configuration of the light emitting apparatus according to the first embodiment of the present invention, and is a plan view showing the second substrate, the adjusting layer, and the barrier member.

FIG. 1B relates to the configuration of the light emitting apparatus according to the first embodiment of the present invention, and is a cross-sectional view of the light emitting apparatus along a plane which includes the center part of the adjusting layer and is parallel to one side constituting the outer edge of the adjusting layer.

FIG. 1C relates to the configuration of the light emitting apparatus according to the first embodiment of the present invention, and is a cross-sectional view of the light emitting apparatus along a plane including a diagonal line of the outer shape of the adjusting layer.

FIG. 2A relates to the configuration of the light emitting apparatus according to the second embodiment of the present invention, and is a plan view showing the second substrate, the adjusting layer, and the barrier member.

FIG. 2B relates to the configuration of the light emitting apparatus according to the second embodiment of the present invention, and is a cross-sectional view of the light emitting apparatus along a plane which includes the center part of the adjusting layer and is parallel to one side constituting the outer edge of the adjusting layer.

FIG. 2C relates to the configuration of the light emitting apparatus according to the second embodiment of the present invention, and is a cross-sectional view of the light emitting apparatus along a plane including a diagonal line of the outer shape of the adjusting layer.

FIG. 3 is a plan view showing a modified example of the adjusting layer in one embodiment of the present invention.

FIG. 4A relates to the configuration of the light emitting apparatus according to the third embodiment of the present invention, and is a plan view showing the second substrate, the adjusting layer, and the barrier member.

FIG. 4B relates to the configuration of the light emitting apparatus according to the third embodiment of the present invention, and is a cross-sectional view of the light emitting apparatus along a plane including the center of the adjusting layer.

FIG. 5A relates to the configuration of the light emitting apparatus according to the fourth embodiment of the present invention, and is a plan view showing the second substrate, the adjusting layer, and the barrier member.

FIG. 5B relates to the configuration of the light emitting apparatus according to the fourth embodiment of the present invention, and is a cross-sectional view of the light emitting apparatus along a plane which includes the center part of the adjusting layer and is parallel to a long side constituting the outer edge of the adjusting layer.

FIG. 5C relates to the configuration of the light emitting apparatus according to the fourth embodiment of the present invention, and is a cross-sectional view of the light emitting apparatus along a plane which includes the center part of the adjusting layer and is parallel to a short side constituting the outer edge of the adjusting layer.

FIG. 6 is a cross-sectional view showing an example of the lighting apparatus including the light emitting apparatus according to the present invention.

FIG. 7 is a cross-sectional view showing a configuration according to a conventional technique.

### DESCRIPTION OF EMBODIMENTS

The light emitting apparatus 1a according to the first embodiment of the present invention includes a first substrate 2a, a light emitting element 4a, a second substrate 3a, an adjusting layer 5a, a barrier member 6a, and a sealing member 7a. The light emitting element 4a is supported on the first substrate 2a. The light emitting element 4a includes a surface 14a, and the light emitting element 4a is supported on the surface 14a. The second substrate 3a is disposed so as to be spaced from and face the surface 14a of the first substrate 2a on which the light emitting element 4a is supported. The adjusting layer 5a is supported on a surface 15a of the second substrate 3a facing the light emitting element 4a. The barrier member 6a is disposed between the first substrate 2a and the second substrate 3a so as to surround the light emitting element 4a and the adjusting layer 5a. The sealing member 7a fills a space 17a surrounded by the first substrate 2a, the second substrate 3a, and the barrier member 6a. Furthermore, the adjusting layer 5a includes a surface 16a facing the first substrate 2a and including an adjusting surface 8a. The adjusting layer 5a is formed so that a distance between the adjusting surface 8a and the first substrate 2a becomes greater towards an outer edge of the adjusting layer 5 than at a center part of the adjusting layer 5.

In the present embodiment, the sealing member 7a fills the space 17a around the light emitting element 4a. The space 17a is a three-dimensional region surrounded by the first substrate 2a, the second substrate 3a, and the barrier member 6a, and the region need not necessarily be occupied by an object. In the present embodiment, the light emitting element 1a, the adjusting layer 5a, and the sealing member 7a are present in the space 17a. The space 17a may include portion which is not occupied by the light emitting element 1a, the adjusting layer 5a, and the sealing member 7a.

When the light emitting apparatus 1a according to the present embodiment is manufactured, the light emitting element 4a is easily enclosed by spreading the sealing member 7a between the first substrate 2a and the second substrate 3a. In addition, since the distance between the adjusting layer 5a and the first substrate 2a becomes greater towards the outer edge of the adjusting layer 5a, a stress applied to the barrier member 6a by the sealing member 7a is reduced. For this reason, deformation and breakage of the barrier member 6a are suppressed.

In the present embodiment, the adjusting surface 8a is preferably designed as a lateral surface of a conical solid or a lateral surface of a frustum. The conical solid may be a circular conical solid or a polygonal conical solid. The conical solid may have a vertex portion being sharpened or designed as a curved surface. That is, when the adjusting surface 8a is designed as the lateral surface of the conical solid, the vertex portion of the adjusting surface 8a may be sharpened or designed as a curved surface. When the conical solid is the polygonal conical solid, a ridge line portion of the lateral surface of the conical solid may be designed as a curved surface. That is, when the adjusting surface 8a is designed as the lateral surface of the polygonal conical solid, the ridge line portion of the adjusting surface 8a may be designed as a curved surface. The frustum may be a circular frustum or a polygonal frustum. When the frustum is the polygonal frustum, a ridge line portion of the lateral surface of the frustum may be designed as a curved surface. That is, when the adjusting surface 8a is designed as the lateral surface of the polygonal frustum, the ridge line portion of the adjusting surface 8a may be designed as a curved surface.

For example, in the present embodiment, the adjusting surface 8a is preferably a curved surface designed as a surface of a circular frustum formed so as to surround the center part of the adjusting layer 5a, i.e., a surface designed as the lateral surface of the circular frustum.

In this case, when the sealing member 7a is spread between the first substrate 2a and the second substrate 3a, a stress applied to the barrier member 6a by the sealing member 7a is less likely to be uneven. For this reason, deformation and breakage of the barrier member 6a are further suppressed.

In the present embodiment, the surface 16a of the adjusting layer 5a facing the first substrate 2a preferably includes a flat surface (outer edge surface 10a) which is closer to the outer edge of the adjusting layer 5a than the adjusting surface 8a is.

In this case, the outer edge surface 10a totally provides a constant thickness of the adjusting layer 5a at the outer edge thereof, and thereby a stress applied to the barrier member 6a by the sealing member 7a is less likely to be uneven. For this reason, deformation and breakage of the barrier member 6a are further suppressed.

In the present embodiment, a thickness of the adjusting layer 5a at the outer edge thereof is preferably a half or less of a thickness of the adjusting layer 5a at the center part thereof.

In this case, at the outer edge of the adjusting layer 5a, the distance between the adjusting layer 5a and the first substrate 2a is sufficiently greater. For this reason, a stress applied to the barrier member 6a by the sealing member 7a is particularly reduced. For this reason, deformation and breakage of the barrier member 6a are further suppressed.

In the present embodiment, the adjusting layer 5a is preferably made of resin.

This provides high affinity between the adjusting layer 5a and the sealing member 7a, which provides an improvement in adhesiveness between the adjusting layer 5a and the sealing member 7a.

Hereinafter, specific embodiments of the present invention will be further described.

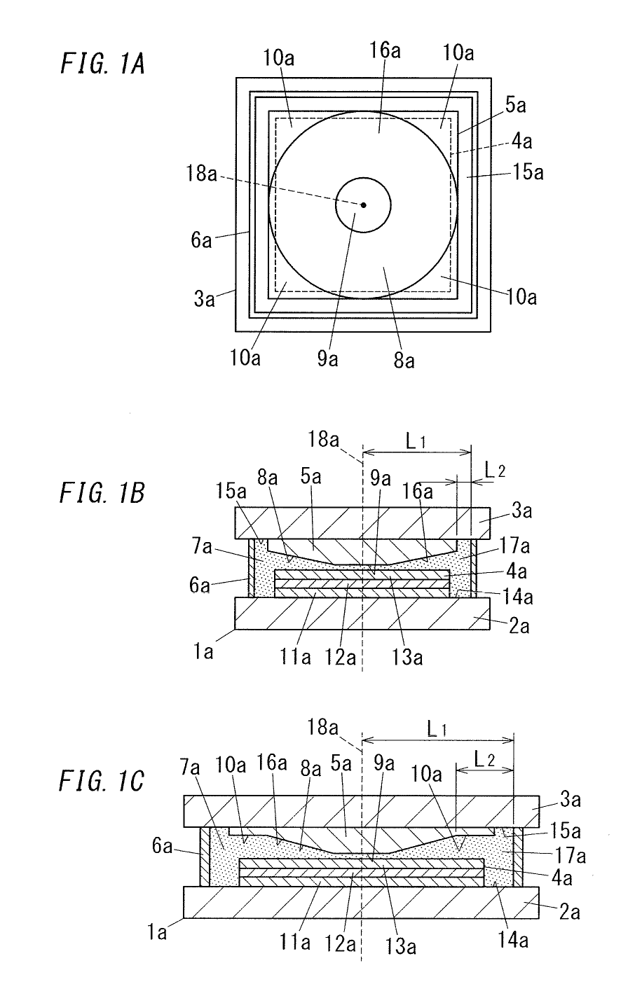

The light emitting apparatus 1a according to the first embodiment is shown in FIGS. 1A, 1B, and 1C. FIG. 1A is a plan view showing the second substrate 3a, the adjusting layer 5a, and the barrier member 6a in the light emitting apparatus 1a, and the position of the light emitting element 4a is shown by a dashed line in FIG. 1A. FIG. 1B is a cross-sectional view of the light emitting apparatus 1a along a plane which includes the center portion of the adjusting layer and is parallel to one side constituting the outer edge of the adjusting layer 5a. FIG. 1C is a cross-sectional view of the light emitting apparatus 1a along a plane including a diagonal line of the outer shape of the adjusting layer 5a.

In the first embodiment, the first substrate 2a is formed in a rectangular plate shape in plan view. The plan view means a view in a direction in which the first substrate 2a and the second substrate 3a face each other. In other words, the plan view means a view of the light emitting apparatus 1a in a direction perpendicular to the surface 14a of the first substrate 2a. The plan view shape of the first substrate 2a in the present embodiment is a rectangular shape, and may be, for example, a polygonal shape such as a triangle shape or a square shape, and a circular shape. The material of the first substrate 2 is not particularly limited, and the first substrate 2 is preferably light transmissive. The phrase “light transmissive” means a property of a substance through which light is transmitted, and includes “translucent” and “transparent”. When a glass substrate is employed as the first substrate 2a, glass has low water permeability, and moisture is particularly less likely to be infiltrated in the light emitting apparatus 1a.

The light emitting element 4a is supported on the first substrate 2a. The phrase “supported on the first substrate 2a” includes not only the case where the light emitting element 4a is directly situated on the first substrate 2a but also the case where the light emitting element 4a is situated on the first substrate 2a with an appropriate layer such as a light extraction layer in-between. The light extraction layer is defined as a layer for increasing an amount of light which is emitted from the light emitting element 4a and emerges outside the light emitting apparatus 1a. Examples of the light extraction layer include a layer made of resin or glass having a refractive index higher than that of the first substrate 2a, and a layer made of resin including light-scattering particles.

In the present embodiment, the light emitting element 4a is supported on the surface 14a of the first substrate 2a. The light emitting element 4a is not particularly limited, but is an organic electroluminescence element (organic light emitting diode), for example. The organic electroluminescence element includes, for example, a first electrode 11a situated on the first substrate 2a, a second electrode 13a paired with the first electrode 11a, and a light-emitting part interposed between the first electrode 11a and the second electrode 13a.

The first electrode 11a functions as a positive electrode, and the second electrode 13afunctions as a negative electrode. Alternatively, the first electrode 11a may function as the negative electrode, and the second electrode 13a may function as the positive electrode.

The first electrode 11a is preferably light transmissive. In this case, light emitted from an organic layer is allowed to emerge outside via the first electrode 11a. The first electrode 11a is preferably made of a transparent conductive material such as ITO and IZO.

On the other hand, the second electrode 13a is preferably light reflective. In this case, light directed to the second electrode 13a from the organic layer is reflected by the second electrode 13a, and the reflected light is allowed to emerge outside via the first electrode 11a. The second electrode 13a is preferably made of metal such as Al or Ag.

Alternatively, the first electrode 11a may be a light reflective electrode, and the second electrode 13a may be a light transmissive electrode. Alternatively, both the first electrode 11a and the second electrode 13a may be light transmissive electrodes.

The thicknesses of the first electrode 11a and the second electrode 13a are not particularly limited, but are within a range of, for example, 10 to 300 nm.

The light-emitting part includes a light-emitting layer 12a which is to emit light when an electric field is applied. The light-emitting part may further include one or more layers selected from a hole injection layer, a hole transport layer, an electron transport layer, an electron injection layer, and an intermediate layer if needed. Materials included in the PRP layers can be appropriately selected from known materials suitable for the organic electroluminescence element. The thickness of the light-emitting part is not particularly limited, but is within a range of, for example, 60 to 300 nm.

A conductor wiring (not shown) connected to the first electrode 11a and a conductor wiring (not shown) connected to the second electrode 13a may be further formed on the first substrate 2a if needed.

The second substrate 3a is spaced from and face the surface 14a of the first substrate 2a on which the light emitting element 4a is supported. In the first embodiment, the second substrate 3a is formed in a rectangular plate shape in plan view. The material of the second substrate 3a is not particularly limited, but the second substrate 3a preferably has low water permeability. In this case, moisture is less likely to be infiltrated in the light emitting apparatus 1a. When a glass substrate is employed as the second substrate 3a, glass has low water permeability, and moisture is particularly less likely to be infiltrated in the light emitting apparatus 1a.

The adjusting layer 5a is supported on the surface 15a of the second substrate 3a facing the light emitting element 4a. The phrase “supported on the surface 15a of the second substrate 3a facing the light emitting element 4a” includes not only the case where the adjusting layer 5a is directly situated on the second substrate 3a but also the case where the adjusting layer 5a is situated on the second substrate 3a with a layer other than the adjusting layer 5a in-between.

The adjusting layer 5a is formed in, for example, a rectangular shape in plan view. In the first embodiment, the adjusting layer 5a is formed in a square shape in plan view.

The adjusting layer 5a includes the surface 16a facing the first substrate 2a and including the adjusting surface 8a. The adjusting layer 5a is formed so that a distance between the adjusting surface 8a and the first substrate 2a becomes greater towards the outer edge of the adjusting layer 5a than at the center part of the adjusting layer 5a. In this case, the center part means a position of a center of gravity of a projected region of the adjusting layer 5a in plan view.

In the first embodiment, the surface 16a of the adjusting layer 5a facing the first substrate 2a includes a flat surface (center surface 9a) including the center part, the adjusting surface 8a formed around the center surface 9a, and the flat surface (outer edge surface 10a) which is closer to the outer edge of the adjusting layer 5 than the adjusting surface 8a is.

In the first embodiment, the center surface 9a is formed in a circular shape in plan view. When such a flat center surface 9a is formed, the adjusting layer 5a suppresses an increase in the distance between the first substrate 2a and the second substrate 3a, and suppresses damage of the light emitting element 4a when the adjusting layer 5a is brought into contact with the light emitting element 4a in case.

In the present embodiment, the adjusting surface 8a is a concentric curved surface. The phrase “the adjusting surface 8a is a concentric curved surface” means that a shape of the adjusting surface 8a present in a section of the adjusting layer 5a along a plane perpendicular to a direction of plan view is circular about the center part and a diameter thereof increases as the section comes close to the second substrate 3a. In this case, the circular shape may include not only a true circular shape but also an elliptical shape. In other words, the adjusting surface 8a is a curved surface designed as a lateral surface of a circular frustum formed so as to surround the center part of the adjusting layer 5a.

In the first embodiment, the adjusting surface 8a has a linear shape on a section of the adjusting layer 5a along a surface including the center part in a direction of plan view, as shown in FIGS. 1B and 1C. The sectional shape may be a curve shape swelling towards the first substrate 2a, or a curve shape recessed towards the second substrate 3a.

In the first embodiment, the adjusting surface 8a has a circular outer circumference in plan view, and the outer circumference of the adjusting surface 8a is inscribed in the outer edge of the adjusting layer 5a in plan view.

Thus, the concentric curved surface of the adjusting surface 8a is less likely to produce a force unevenly applied to the barrier member 6a by the sealing member 7a when the sealing member 7a is spread between the first substrate 2a and the second substrate 3a and the periphery of the sealing member 7a moves towards the circumference of the adjusting layer 5a from the center part of the adjusting layer 5a.

In the first embodiment, the outer edge surface 10a includes four corners of a surface of the adjusting layer 5a facing the first substrate 2a. By forming the outer edge surface 10a, a constant thickness of the adjusting layer 5a is formed over all at the outer edge thereof. For this reason, a force is further less likely to be unevenly applied to the barrier member 6a from the sealing member 7a.

The thickness of the adjusting layer 5a at the outer edge thereof is preferably a half or less of the distance between the first substrate 2a and the second substrate 3a, and particularly preferably a half or less of the thickness of the adjusting layer 5a at the center part thereof. In this case, the distance between the adjusting layer 5a and the first substrate 2a at the outer edge of the adjusting layer 5a becomes sufficiently greater. For this reason, the stress applied to the barrier member 6 by the sealing member 7a is particularly reduced. The thickness of the adjusting layer 5a at the outer edge thereof is particularly preferably within a range of ⅓ to ⅔ of the thickness of the adjusting layer 5a at the center part thereof, and more preferably within a range of ⅓ to ½.

The maximum thickness of the adjusting layer 5a (the thickness of the adjusting layer 5a at the center part in the present embodiment) is preferably within a range of ⅙ to ⅔ of the distance between the first substrate 2a and the second substrate 3a. In this case, an effect of reducing the stress applied to the barrier member 6a by the sealing member 7a is sufficiently secured, and an increase in the distance between the first substrate 2a and the second substrate 3a is suppressed. This can contribute to size reduction and thinning of the light emitting apparatus 1a.

The material of the adjusting layer 5a is not limited, but the adjusting layer 5a is particularly preferably made of resin. This provides high affinity between the adjusting layer 5a and the sealing member 7a, which provides an improvement in adhesiveness between the adjusting layer 5a and the sealing member 7a.

When the adjusting layer 5a is made of resin, the adjusting layer 5a is made of for example, an appropriate resin composition such as a thermosetting resin composition, a photo-curable resin composition, or a thermoplastic resin composition. Specific examples of resins which may be included in the resin composition include phenol resin, melamine resin, epoxy resin, polyurethane, urea resin, alkyd resin, and unsaturated polyester resin. The adjusting layer 5a is formed by an appropriate technique. The adjusting layer 5a is formed by, for example, printing. When the adjusting layer 5a is formed by printing, the number of steps required in order to form the adjusting layer 5a can be reduced, which contributes also to cost reduction. Specifically, for example, a photo-curable resin composition is applied on the second substrate 3a, and molded by a photolithographic method. Thereby, the adjusting layer 5a can be formed. The adjusting layer 5a may be formed on the second substrate 3a by injection forming or the like in a state where the second substrate 3a is inserted into a mold. The adjusting layer 5a may be joined on the second substrate 3a after the adjusting layer 5a is formed by an appropriate technique.

The adjusting layer 5a may be made of a material other than the resin. For example, the adjusting layer 5a may be made of metal or glass.

The light emitting apparatus 1a may include a member including a portion constituted as the second substrate 3a and a portion constituted as the adjusting layer 5a. That is, the second substrate 3a and the adjusting layer 5a may constitute one member without providing the adjusting layer 5a which is a member different from the second substrate 3a on the second substrate 3a. The member including the portion constituted as the second substrate 3a and the portion constituted as the adjusting layer 5a is made of, for example, glass.

In the space 17a between the first substrate 2a and the second substrate 3a, the barrier member 6a is disposed along the whole outer edge portion of the space 17a. The barrier member 6a is joined to the first substrate 2a and the second substrate 3a. Thereby, the barrier member 6a is interposed between the first substrate 2a and the second substrate 3a so as to surround the light emitting element 4a and the adjusting layer 5a. The material of the barrier member 6a is not particularly limited, but the barrier member 6a includes, for example, a glass molding made of glass frit or the like and a resin molding made of ultraviolet curing resin or the like. The thickness of the barrier member 6a is not particularly limited. The barrier member 6a is preferably thin from the viewpoints of size reduction and weight reduction of the light emitting apparatus 1a, and the thickness of the barrier member 6a is particularly preferably within a range of 1 to 100 μm.

The sealing member 7a is made of, for example, an appropriate nonconductive resin adhesive. The sealing member 7a is made of, for example, an appropriate nonconductive resin adhesive. For example, the sealing member 7a is made of one or more materials selected from the group consisting of phenol resin, melamine resin, epoxy resin, polyurethane, urea resin, alkyd resin, and unsaturated polyester resin.

In the first embodiment, the adjusting surface 8a is preferably formed so that, with regard to any section of the light emitting apparatus 1a containing a central axis 18a of the space 17a, a percentage of a distance L2 from an outer edge of the adjusting surface 8a to the barrier member 5a to a distance L1 from the central axis 18a to the barrier member 5a is equal to or less than 50%. The central axis 18a of the space 17a is a virtual straight line including a center of gravity of a projected region of the space 17a in plan view, and being parallel to a direction of plan view (that is, perpendicular to the surface 14a of the first substrate 1a). When the sealing member 7a is spread between the first substrate 2a and the second substrate 3a, and the periphery thereof moves towards the circumference of the adjusting layer 5a from the center part of the adjusting layer 5a, provided that the percentage of the distance L2 to the distance L1 is equal to or less than 50%, the sealing member 7a is likely to reach the barrier member 5a, which suppresses failure in filling with the sealing member 7a. However, the force applied to the barrier member 6a by the sealing member 7a is sufficiently suppressed by the adjusting surface 8a, which effectively suppresses breakage of the barrier member 6a. Particularly, the percentage is preferably equal to or greater than 5%; the percentage is also preferably equal to or less than 20%; and the percentage is also preferably within a range of 5 to 20%.

In the first embodiment, each of the first substrate 2a, the second substrate 3a, and the adjusting layer 5a may be light transmissive. When the first substrate 2a, the second substrate 3a, and the adjusting layer 5a are light transmissive, the light emitting apparatus 1a is highly light transmissive, and thereby appearance of the light emitting apparatus 1a and a lighting apparatus including the light emitting apparatus 1a are improved.

A method for manufacturing the light emitting apparatus 1a according to the first embodiment includes: for example, providing the light emitting element 1a and the barrier member 6a on the surface 14a of the first substrate 2a; providing the adjusting layer 5a on the surface 15a of the second substrate 3a; disposing the first substrate 2a and the second substrate 3a so that the surface 14a of the first substrate 2a and the surface 15a of the second substrate 3a face each other; and disposing the sealing member between the light emitting element 1a and the adjusting layer 5a, and spreading the sealing member 7a between the first substrate 2a and the second substrate 3a by pressing the sealing member 7a by the adjusting layer 5a while relatively moving the first substrate 2a close to the second substrate 3a until the barrier member 6a comes into contact with the second substrate 3a.

When the light emitting apparatus 1a according to the present embodiment is manufactured, the light emitting element 4a and the barrier member 6a are first provided on the surface 14a of the first substrate 2a, for example. Meanwhile, the adjusting layer 5a is provided on the surface 15a of the second substrate 3a.

The first substrate 2a and the second substrate 3a are disposed so that the light emitting element 4a and the adjusting layer 5a respectively supported on the first substrate 2a and the second substrate 3a face each other. That is, the first substrate 2a and the second substrate 3a are disposed so that the surface 14a of the first substrate 2a and the surface 15a of the second substrate 3a face each other. Furthermore, the sealing member 7a is disposed between the light emitting element 4a and the adjusting layer 5a. In this state, the first substrate 2a is relatively moved close to the second substrate 3a until the barrier member 6a comes into contact with the second substrate 3a. Furthermore, the barrier member 6a is joined to the second substrate 3a. Thereby, the light emitting element 4a is sealed by the sealing member 7a, to obtain the light emitting apparatus 1a.

In the process in which the light emitting apparatus 1a is manufactured thus, the sealing member 7a is spread between the first substrate 2a and the second substrate 3a by pressing the sealing member 7a by the adjusting layer 5a. Since the adjusting surface 8a is formed on the adjusting layer 5a at this time, the distance between the adjusting layer 5a and the first substrate 2a becomes greater towards the outer edge as described above, and thereby the force applied to the barrier member 6a by the sealing member 7a is reduced. For this reason, deformation and breakage of the barrier member 6a are suppressed.

From the above, in the present embodiment, the light emitting element 4a is easily enclosed by the sealing member 7a, and the light emitting apparatus 1a is obtained with high yield.

The configuration of the light emitting apparatus is not limited to that of the first embodiment. For example, the shape of the adjusting surface is not limited to that of the first embodiment. In the first embodiment, the adjusting layer 5a is formed so that the distance between the adjusting surface 8a and the first substrate 2a continuously becomes greater towards the outer edge of the adjusting layer 5a than at the center part of the adjusting layer 5a. The adjusting layer 5a may be formed so that the distance discontinuously becomes greater. That is, the adjusting surface may be stepwisely formed, for example.

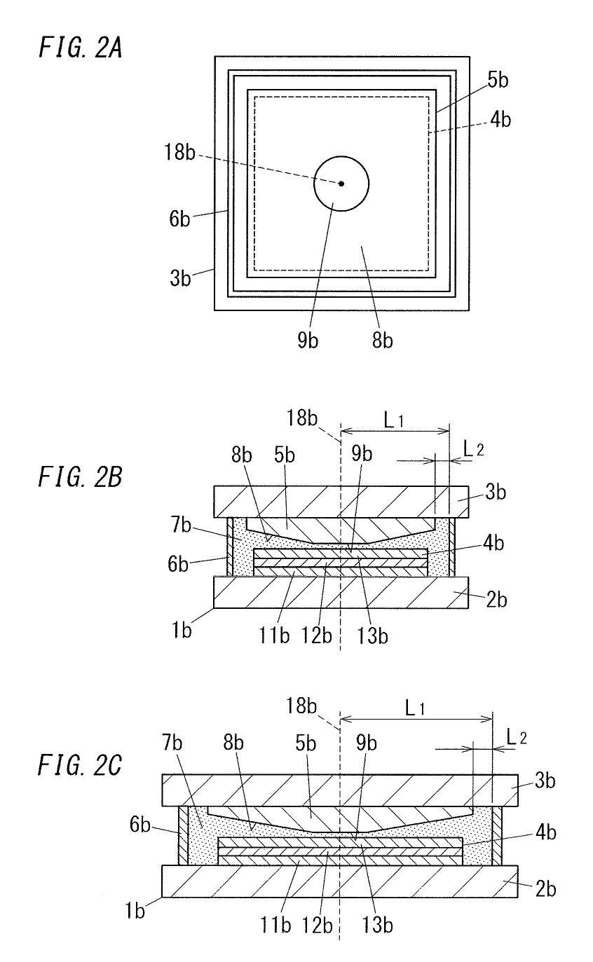

The surface of the adjusting layer facing the first substrate may not include the flat outer edge surface. As an example of the light emitting apparatus in this case, a light emitting apparatus 1b according to a second embodiment is shown in FIGS. 2A, 2B, and 2C.

FIG. 2A is a plan view showing a second substrate 3b, an adjusting layer 5b, and a barrier member 6b in the light emitting apparatus 1b, and the position of a light emitting element 4b is shown by a dashed line in FIG. 2A. FIG. 2B is a cross-sectional view of the light emitting apparatus 1b along a plane which includes the center part of the adjusting layer 5b and is parallel to one side constituting an outer edge of the adjusting layer 5b. FIG. 2C is a cross-sectional view of the light emitting apparatus 1b along a plane including a diagonal line of the outer shape of the adjusting layer 5b.

The light emitting apparatus 1b according to the present embodiment has the same structure as the light emitting apparatus 1a according to the first embodiment except that an outer edge surface is not formed in the adjusting layer 5b.

That is, the light emitting apparatus 1b according to the second embodiment includes a first substrate 2b a light emitting element 4b, a second substrate 3b, an adjusting layer 5b, a barrier member 6b, and a sealing member 7b. The light emitting element 4b is supported on the first substrate 2b. The light emitting element 4b includes a surface 14b, and the light emitting element 4b is supported on the surface 14b. The second substrate 3b is disposed so as to be spaced from and facing the surface 14b of the first substrate 2b on which the light emitting element 4b is supported. The adjusting layer 5b is supported on a surface 15b of the second substrate 3b facing the light emitting element 4b. The barrier member 6b is disposed between the first substrate 2b and the second substrate 3b so as to surround the light emitting element 4b and the adjusting layer 5b. The sealing member 7b fills a space 17b surrounded by the first substrate 2b, the second substrate 3b, and the barrier member 6b. Furthermore, the adjusting layer 5b includes a surface 16b which faces the first substrate 2b and includes an adjusting surface 8b. The adjusting layer 5b is formed so that a distance between the adjusting surface 8b and the first substrate 2b becomes greater towards an outer edge of the adjusting layer 5b than at a center part of the adjusting layer 5b.

In the second embodiment, the first substrate 2b, the light emitting element 4b, the second substrate 3b, the barrier member 6b, and the sealing member 7b respectively have the same configurations as the first substrate 2a, the light emitting element 4a, the second substrate 3a, the barrier member 6a, and the sealing member 7a in the first embodiment. The adjusting layer 5b in the second embodiment has the same configuration as the adjusting layer 5a in the first embodiment except that an outer edge surface is not formed.

Also in the second embodiment, the adjusting surface 8b is preferably formed so that, with regard to any section of the light emitting apparatus 1b containing a central axis 18b of the space 17b, a percentage of a distance L2 from an outer edge of the adjusting surface 8b to the barrier member 5b to a distance L1 from the central axis 18b to the barrier member 5b is equal to or less than 50%. Particularly, the percentage is preferably equal to or greater than 5%; the percentage is also preferably equal to or less than 20%; and the percentage is also preferably within a range of 5 to 20%.

A method for manufacturing the light emitting apparatus 1b according to the second embodiment includes: for example, providing the light emitting element 1b and the barrier member 6b on the surface 14b of the first substrate 2b; providing the adjusting layer 5b on the surface 15b of the second substrate 3b; disposing the first substrate 2b and the second substrate 3b so that the surface 14b of the first substrate 2b and the surface 15b of the second substrate 3b face each other; and disposing the sealing member between the light emitting element 1b and the adjusting layer 5b, and spreading the sealing member 7b between the first substrate 2b and the second substrate 3b by pressing the sealing member 7b by the adjusting layer 5b while relatively moving the first substrate 2b close to the second substrate 3b until the barrier member 6b comes into contact with the second substrate 3b.

As in the case of the first embodiment, the adjusting surface 8b is a concentric curved surface in the second embodiment, and the outer circumference of the adjusting surface 8b coincides with the outer edge of the adjusting layer 5b in plan view.

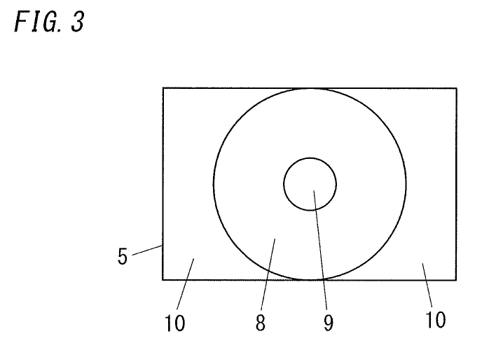

In the first and second embodiments, each of the adjusting layer 5a and the adjusting layer 5b has a square shape in plan view. Of course, the shape of the adjusting layer in plan view is not limited thereto. The adjusting layer is formed in an appropriate shape in plan view in accordance with the shape of the light emitting apparatus. For example, the adjusting layer may have a rectangular shape in plan view. An example of the shape of the adjusting layer in plan view in the case is shown in FIG. 3. In the adjusting layer 5, a surface 16 facing a first substrate 2 includes a flat center surface 9 having a circular shape in plan view, a concentric adjusting surface 8 surrounding the center surface 9, and a flat outer edge surface 10 located outside the adjusting surface 8. The adjusting surface 8 has a circular outer circumference. The outer circumference is inscribed in two long sides of four sides constituting an outer edge the outer edge of the adjusting layer 5. The outer circumference of the adjusting surface 8 and each of two short sides of four sides constituting the outer edge of the adjusting layer 5 are spaced from each other. The outer edge surface 10 is formed between the outer circumference of the adjusting surface 8 and the short side. The outer circumference of the adjusting surface 8 and the outer edge of the adjusting layer 5 may coincide with each other without forming the outer edge surface 10.

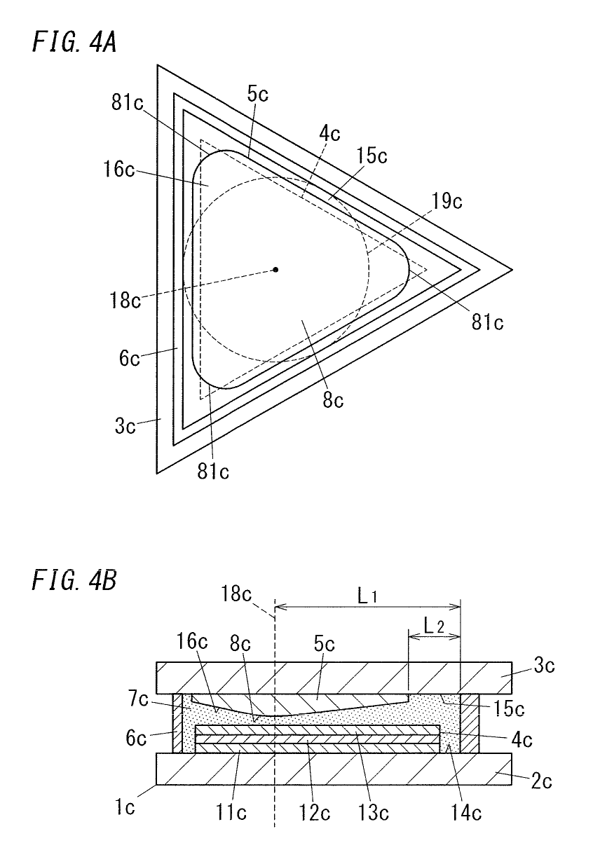

The light emitting apparatus 1c according to the third embodiment is shown in FIGS. 4A and 4B.

FIG. 4A is a plan view showing a second substrate 3c, an adjusting layer 5c, and a barrier member 6c in the light emitting apparatus 1c, and the position of a light emitting element 4c is shown by a dashed line in FIG. 4A. FIG. 2B is a cross-sectional view of the light emitting apparatus 1c along a plane including a center part of the adjusting layer 5b.

The light emitting apparatus 1c according to the third embodiment includes a first substrate 2c, a light emitting element 4c, a second substrate 3c, an adjusting layer 5c, a barrier member 6c, and a sealing member 7c. The light emitting element 4c is supported on the first substrate 2c. The light emitting element 4c includes a surface 14c, and the light emitting element 4c is supported on the surface 14c. The second substrate 3c is disposed so as to be spaced from and facing the surface 14c of the first substrate 2c on which the light emitting element 4c is supported. The adjusting layer 5c is supported on a surface 15c of the second substrate 3c facing the light emitting element 4c. The barrier member 6c is disposed between the first substrate 2c and the second substrate 3c so as to surround the light emitting element 4c and the adjusting layer 5c. The sealing member 7c fills a space 17c surrounded by the first substrate 2c, the second substrate 3c, and the barrier member 6c. Furthermore, the adjusting layer 5c includes a surface 16c facing the first substrate 2c and including an adjusting surface 8c. The adjusting layer 5c is formed so that a distance between the adjusting surface 8c and the first substrate 2c becomes greater towards an outer edge of the adjusting layer 5c than at a center part of the adjusting layer 5c.

Each of the first substrate 2c and the second substrate 3c in the third embodiment has a triangle plate shape in plan view. Except for this, the first substrate 2c and the second substrate 3c respectively have the same configurations as the first substrate 2a and the second substrate 3a in the first embodiment.

In the third embodiment, the surface 16c of the adjusting layer 5c includes the adjusting surface 8c, and the adjusting surface 8c is designed as a lateral surface of a trigonal pyramid. In the present embodiment, the adjusting layer 5c has a triangle shape in plan view, and the surface 16c of the adjusting surface 5c includes the adjusting surface 8c.

In the present embodiment, the adjusting layer 5c includes a vertex portion including a curved surface, and a ridge line portion including a curved surface. In conjunction with this configuration, the adjusting layer 5c has a triangle shape and includes curved vertex portions in plan view. For this reason, the adjusting surface 8c has a triangle shape and includes curved vertex portions 81c in plan view.

The adjusting layer 5c has the same configuration as the adjusting layer 5a in the first embodiment except that the adjusting layer 5c has such a shape.

In the space 17c between the first substrate 2c and the second substrate 3c, the barrier member 6c is disposed along the whole outer edge portion of the space 17c. The barrier member 6c is joined to the first substrate 2c and the second substrate 3c. Thereby, the barrier member 6c is interposed between the first substrate 2c and the second substrate 3c so as to surround the light emitting element 4c and the adjusting layer 5c.

In the present embodiment, the barrier member 6c is formed in a triangle frame shape in plan view so as to coincide with the shape of each of the outer edges of the first substrate 2c and the second substrate 3c.

The barrier member 6c has the same configuration as the barrier member 6a in the first embodiment except that the barrier member 6c has such a shape.

The sealing member 7c has the same configuration as the sealing member 7a in the first embodiment.

Also in the third embodiment, the adjusting surface 8c is preferably formed so that, with regard to any section of the light emitting apparatus 1c containing a central axis 18c of the space 17c, a percentage of a distance L2 from an outer edge of the adjusting surface 8c to the barrier member 5c to a distance L1 from the central axis 18c to the barrier member 5c is equal to or less than 50%. Particularly, the percentage is preferably equal to or greater than 5%; the percentage is also preferably equal to or less than 20%; and the percentage is also preferably within a range of 5 to 20%.

In the present embodiment, the curvature radius of a vertex portion 81c in the shape of the adjusting surface 8c in plan view is preferably equal to or less than ½ of the radius of a virtual inscribed circle 19c inscribed in the space 17c in plan view. In this case, the curvature radius of the vertex portion 81c of the adjusting surface 8c is small, and thereby the vertex portion 81c of the adjusting surface 8c can be disposed so as to be close to a corner portion of the space 17c. For this reason, the sealing member 7c pressed by the adjusting surface 8c is likely to reach the corner portion of the space 17c. Thereby, failure in the filling with the sealing member 7c is suppressed. The curvature radius c of the vertex portion 81 is particularly preferably within a range of ¼ to ½ of the radius of the inscribed circle 19c, and more preferably within a range of ⅓ to ½.

The above-mentioned preferable condition for the inscribed circle 19c and the vertex portion 81c is not limited to the case where the space 17c has a triangle shape and the adjusting surface 8c also has a triangle shape as in the present embodiment. That is, when the space 17c has a polygonal shape and the adjusting surface 8c also has the same polygonal shape, the curvature radius of the vertex portion 81c in the shape of the adjusting surface 8c in plan view is preferably equal to or less than ½ of the radius of the virtual inscribed circle 19c inscribed in the space 17c in plan view, more preferably within a range of ¼ to ½, and still more preferably within a range of ⅓ to ½.

A method for manufacturing the light emitting apparatus 1c according to the third embodiment includes: for example, providing the light emitting element 1c and the barrier member 6c on the surface 14c of the first substrate 2c; providing the adjusting layer 5c on the surface 15c of the second substrate 3c; disposing the first substrate 2c and the second substrate 3c so that the surface 14c of the first substrate 2c and the surface 15c of the second substrate 3c face each other; and disposing the sealing member between the light emitting element 1c and the adjusting layer 5c, and spreading the sealing member 7c between the first substrate 2c and the second substrate 3c by pressing the sealing member 7c by the adjusting layer 5c while relatively moving the first substrate 2c close to the second substrate 3c until the barrier member 6c comes into contact with the second substrate 3c.

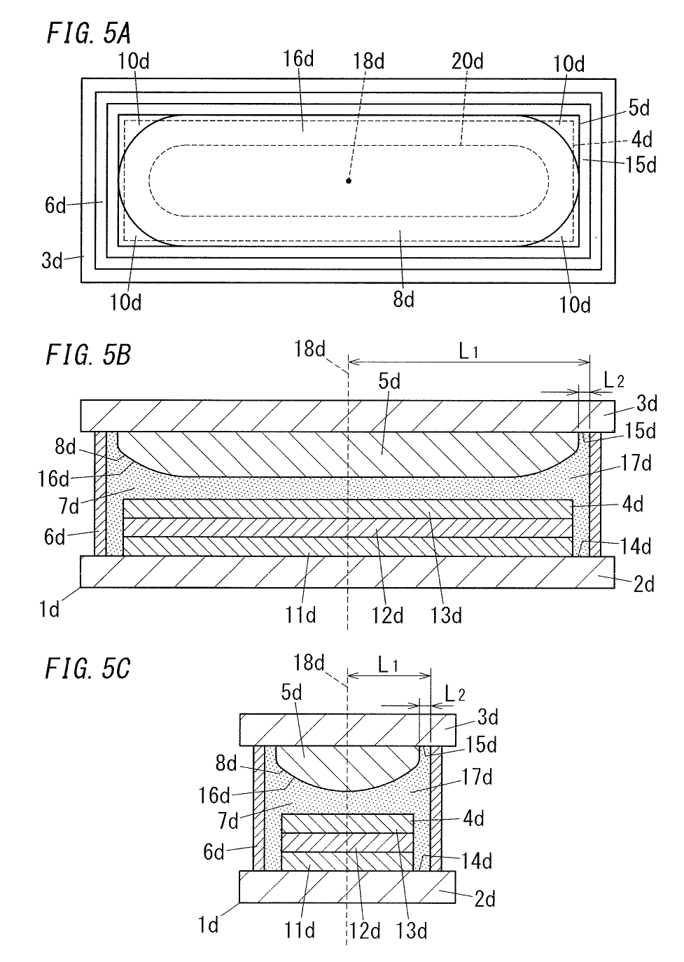

The light emitting apparatus 1d according to the fourth embodiment is shown in FIGS. 5A, 5B, and 5C. FIG. 5A is a plan view showing a second substrate 3d, an adjusting layer 5d, and a barrier member 6d in the light emitting apparatus 1d, and the position of a light emitting element 4d is shown by a dashed line in FIG. 5A. FIG. 5B is a cross-sectional view (longitudinal cross-sectional view) of the light emitting apparatus 1d along a plane which includes a center part of the adjusting layer 5d and is parallel to a long side constituting an outer edge of the adjusting layer 5d. FIG. 5C is a cross-sectional view (longitudinal cross-sectional view) of the light emitting apparatus 1d along a plane which includes the center part of the adjusting layer 5d and is parallel to a short side constituting the outer edge of the adjusting layer 5d.

The light emitting apparatus 1d according to the fourth embodiment includes a first substrate 2d, a light emitting element 4d, a second substrate 3d, an adjusting layer 5d, a barrier member 6d, and a sealing member 7d. The light emitting element 4d is supported on the first substrate 2d. The light emitting element 4d includes a surface 14d, and the light emitting element 4d is supported on the surface 14d. The second substrate 3d is disposed so as to be spaced from and facing the surface 14d of the first substrate 2d on which the light emitting element 4d is supported. The adjusting layer 5d is supported on a surface 15d of the second substrate 3d facing the light emitting element 4d. The barrier member 6d is disposed between the first substrate 2d and the second substrate 3d so as to surround the light emitting element 4d and the adjusting layer 5d. The sealing member 7d fills a space 17d surrounded by the first substrate 2d, the second substrate 3d, and the barrier member 6d. Furthermore, the adjusting layer 5d includes a surface 16d facing the first substrate 2d and including an adjusting surface 8d. The adjusting layer 5d is formed so that a distance between the adjusting surface 8d and the first substrate 2d becomes greater towards an outer edge of the adjusting layer 5d than at a center part of the adjusting layer 5d.

In the present embodiment, the space 17d is elongated in a direction along the surface 15d of the second substrate 3d. Furthermore, the adjusting surface 8d is formed so that a region enclosed by any contour line 20d on the adjusting surface 8d on the basis of the surface 15d of the second substrate 3d is elongated in the direction. In other words, the adjusting surface 8d is formed so that any section of the adjusting layer 5d being parallel to the surface 15d of the second substrate 3d and crossing the adjusting surface 8d is elongated in the direction.

For this reason, although the space 17d is elongated in the direction in the present embodiment, the sealing member 7d pressed by the adjusting surface 8d is likely to thoroughly fill the space 17d. Thereby, failure in the filling with the sealing member 7d is suppressed.

The configuration of the light emitting apparatus 1d according to the fourth embodiment will be described in more detail.

Each of the first substrate 2d and the second substrate 3d in the fourth embodiment has a rectangular plate shape in plan view. Except for this, the first substrate 2c and the second substrate 3c respectively have the same configurations as the first substrate 2a and the second substrate 3a in the first embodiment.

In the present embodiment, the barrier member 6d is formed in a rectangular frame shape in plan view so as to coincide with the shape of each of the outer edges of the first substrate 2d and the second substrate 3d.

The barrier member 6d has the same configuration as the barrier member 6a in the first embodiment except that the barrier member 6d has the aforementioned shape.

The space 17d is elongated in a direction along the surface 14d of the second substrate 2d. In the present embodiment, the space 17d has a rectangular shape in plan view, and is elongated in a direction along the long side of the outer edge of the first substrate 2d.

The adjusting layer 5d is supported on the surface 15d of the second substrate 3d. The adjusting layer 5d is formed in a rectangular shape in plan view. The adjusting layer 5d includes a surface 16d including an adjusting surface 8d. The adjusting layer 5d is formed so that a distance between the adjusting surface 8d and the first substrate 2d becomes greater towards the outer edge of the adjusting layer 5d than at the center part of the adjusting layer 5d. In the present embodiment, the surface 16d of the adjusting layer 5d includes the adjusting surface 8d and a flat surface (outer edge surface 10d) which is closer to the outer edge of the adjusting layer 5d than the adjusting surface 8d is.

The shape of the adjusting surface 8d in plan view in the present embodiment is an ellipse shape elongated in the longitudinal direction of the space 17d (the direction along the long side of the outer edge of the second substrate 3d). The adjusting surface 8d is a curved surface elongated in the longitudinal direction of the space 17d (the direction along the long side of the outer edge of the second substrate 3d) and projected towards the first substrate 2d.

The adjusting surface 8d is formed so that a region enclosed by any contour line 20d on the adjusting surface 8d on the basis of the surface 15d of the second substrate 3d is elongated in the longitudinal direction of the space 17d. The region enclosed by the contour line on the adjusting surface 8d in the present embodiment has an ellipse shape which is similar to the shape of the adjusting surface 8d in plan view, for example. As the position of the contour line is away from the surface 15d of the second substrate 3d, the area of the region enclosed by the contour line is decreased.

In other words, the adjusting surface 8d is formed so that any section of the adjusting layer 5d being parallel to the surface 15d of the second substrate 3d and crossing the adjusting surface 8d is elongated in the longitudinal direction of the space 17d. The shape of the section of the adjusting layer 5d in the present embodiment has an ellipse shape which is similar to the shape of the adjusting surface 8d in plan view, for example. As the position of the section is away from the surface 15d of the second substrate 3d, the area of the section is decreased.

The adjusting layer 5d has the same configuration as the adjusting layer 5a in the first embodiment except that the adjusting layer 5d has the above-mentioned shape.

Since the adjusting surface 8d has the above-mentioned shape, the space 17d is elongated in the direction in the present embodiment, but the sealing member 7d pressed by the adjusting surface 8d is likely to thoroughly fill the space 17d. Thereby, failure in the filling with the sealing member 7d is suppressed.

The sealing member 7d has the same configuration as the sealing member 7a in the first embodiment.

Also in the fourth embodiment, the adjusting surface 8d is preferably formed so that, with regard to any section of the light emitting apparatus 1d containing a central axis 18d of the space 17d, a percentage of a distance L2 from an outer edge of the adjusting surface 8d to the barrier member 5d to a distance L1 from the central axis 18d to the barrier member 5d is equal to or less than 50%. Particularly. the percentage is preferably equal to or greater than 5%; the percentage is also preferably equal to or less than 20%; and the percentaae is also preferably within a ranae of 5 to 20%.

A method for manufacturing the light emitting apparatus 1d according to the fourth embodiment includes: for example, providing the light emitting element 1d and the barrier member 6d on the surface 14d of the first substrate 2d; providing the adjusting layer 5d on the surface 15d of the second substrate 3d; disposing the first substrate 2d and the second substrate 3d so that the surface 14d of the first substrate 2d and the surface 15d of the second substrate 3d face each other; and disposing the sealing member 7d between the light emitting element Id and the adjusting layer 5d, and spreading the sealing member 7d between the first substrate 2d and the second substrate 3d by pressing the sealing member 7d by the adjusting layer 5d while relatively moving the first substrate 2d close to the second substrate 3d until the barrier member 6d comes into contact with the second substrate 3d.

Each of the light emitting apparatuses 1a, 1b, 1c, and 1d is preferable as a light source for a lighting apparatus.

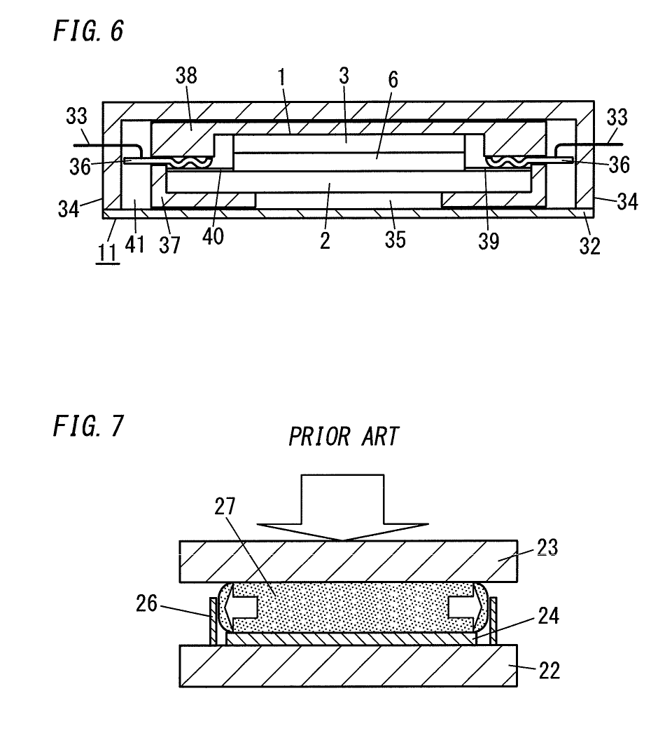

An example of a lighting apparatus 11 including a light emitting apparatus 1 is shown in FIG. 6. The lighting apparatus 11 includes the light emitting apparatus 1, a case 34, a front panel 32, a wiring 33, and a power feeding terminal 36.

The light emitting apparatus 1 includes a first substrate 2, a light emitting element, a second substrate 3, an adjusting layer, a barrier member 6, and a sealing member. The light emitting apparatus 1 has the same structure as the light emitting apparatus 1a according to the first embodiment, for example. That is, for example, the first substrate 2, the light emitting element, the second substrate 3, the adjusting layer, the barrier member 6, and the sealing member in the light emitting apparatus 1 respectively have the same configurations as the first substrate 2a, the light emitting element 4a, the second substrate 3a, the adjusting layer 5a, the barrier member 6a, and the sealing member 7a in the light emitting apparatus 1a according to the first embodiment. The light emitting apparatus 1 may have the same structure as any of the light emitting apparatuses 1b, 1c, and 1d according to the second to fourth embodiments.

A first wiring 39 and a second wiring 40 are formed on the first substrate 2 in the light emitting apparatus 1. The first wiring 39 is connected to a first electrode of the light emitting apparatus 1. The second wiring 40 is connected to a second electrode of the light emitting apparatus 1. A front side case 37 includes an opening 35 which faces the first substrate 2 of the light emitting apparatus 1.

The case 34 holds the light emitting apparatus 1. The case 34 has a recess 41, and the light emitting apparatus 1 is held in the recess 41. The opening of the recess 41 is blocked by the translucent front panel 32.

The two wirings 33 are provided from the outside of the case 34 to the inside. These wirings 33 are connected to an external electrical source. The two power feeding terminals 36 are secured between the front side case 37 and a back side element case 38. The two wirings 33 are connected to the two power feeding terminals 36, and the two power feeding terminals 36 are connected to the first wiring 39 and the second wiring 40. Thereby, a power can be supplied to the light emitting element in the light emitting apparatus 1 via the wirings 33 and the power feeding terminals 36 from the external electrical source.

When a power is supplied to the light emitting element in the light emitting apparatus 1 via the wirings 33 and the power feeding terminals 36 from the external electrical source in the lighting apparatus 11 thus constituted, the light emitting element emits light, and the light is emitted to the outside via the first substrate 2, the opening 35, and the front panel 32.

### EXAMPLES

Hereinafter, specific Examples of the present invention will be provided. The present invention is not limited to the following Examples.

### Example 1

In the present Example, there was prepared a light emitting apparatus having a structure shown in FIGS. 2A, 2B, and 2C. That is, an outer edge surface was not formed on a surface of an adjusting layer facing a first substrate.

In the present Example, there was first prepared an alkali-free glass substrate (part number: 1737 available from Corning Incorporated) having a side of 50 mm and a thickness of 0.7 mm and having a square shape in plan view as the first substrate. A light emitting element (organic electroluminescence element) having a side of 40 mm and having a square shape in plan view was formed on the first substrate.

Furthermore, a barrier member was formed on the first substrate so as to surround the light emitting element. In this case, there was used a UV-curable epoxy adhesive (XNR-5516 available from Nagase ChemteX Corporation) including beads having a diameter of 50 μm. A 10-ml syringe (available from Musashi Engineering, Inc.) was filled with the UV-curable epoxy adhesive. A precision nozzle (available from Musashi Engineering, Inc., nozzle tip diameter: 0.05 mm) was attached to a tip of the syringe. The barrier member was formed by applying the UV-curable epoxy adhesive at a discharge pressure of 0.4 MPa from the syringe with the precision nozzle by using a dispenser (“SHOT MASTER300” available from Musashi Engineering, Inc.). The height of the barrier member was set to 50 μm, and the thickness of the barrier member was set to 2 mm. The length of a side of a region surrounded by the barrier member in plan view was set to 45 mm.

As a second substrate, there was prepared a soda lime glass substrate (part number: 0081 available from Corning Incorporated) having a side of 50 mm and a thickness of 0.7 mm and having a square shape in plan view. An adjusting layer made of aluminum was joined on the second substrate. The length of a side of the adjusting layer in plan view was set to 43 mm. The diameter of a center surface was set to 10 mm. A concentric adjusting surface reaching an outer edge of the adjusting layer was formed around the center surface. The thickness of the adjusting layer at a center part thereof was set to 25 μm. The thickness of the adjusting layer at the outer edge thereof was uniformly adjusted by adjusting the inclination angle of the adjusting surface, to set the value of the thickness to 15.6 μm. That is, the thickness of the adjusting layer at the outer edge thereof was set to be a half of the height of the barrier member (equivalent to a distance between the first substrate and the second substrate), and set to be ⅝ of the thickness of the adjusting layer at the center part thereof.

Next, the first substrate and the second substrate were disposed so that the light emitting element and the adjusting layer face each other. Furthermore, epoxy UV-curable resin was disposed as a sealing member between the light emitting element and the adjusting layer. The amount of the sealing member was adjusted so that the amount was equal to the capacity of a space to be filled with the sealing member. In this state, the first substrate was relatively moved close to the second substrate until the barrier member came into contact with the second substrate. Furthermore, the barrier member was joined to the second substrate. The sealing member was cured by irradiating the sealing member with ultraviolet rays. Thereby, the light emitting apparatus was obtained.

### Example 2

In the present Example, there was produced a light emitting apparatus having a structure shown in FIGS. 1A, 1B, and 1C. That is, an outer edge surface was formed on a surface of an adjusting layer facing a first substrate.

In the present Example, a concentric adjusting surface was formed around the center surface of the adjusting layer in Example 1. The outer circumference of the adjusting surface had a circular shape in plan view, and the outer circumference was inscribed in an outer edge of the adjusting layer. A flat outer edge surface was formed outside the adjusting surface. The thickness of the adjusting layer at a center part thereof was set to 50 μm, and the thickness of the adjusting layer at the outer edge thereof was set to 15.6 μm. That is, the thickness of the adjusting layer at the outer edge thereof was set to be a half of the height of a barrier member (equivalent to a distance between the first substrate and a second substrate), and set to be ⅝ of the thickness of the adjusting layer at the center part thereof.

Except for this, the same method and condition as Example 1 were employed, to obtain the light emitting apparatus.

### Example 3

In the present Example, there was produced a light emitting apparatus having a structure shown in FIGS. 1A, 1B, and 1C.

In the present embodiment, the thickness of an adjusting layer at an outer edge thereof was changed into 5.6 μm in Example 2. That is, the thickness of the adjusting layer at the outer edge thereof was set to 3/10 of the height of a barrier member (equivalent to a distance between a first substrate and a second substrate), and set to be ⅜ of the thickness of the adjusting layer at a center part thereof.

### Example 4

In Example 3, an adjusting layer was formed of photo-curable resin (part number: PAK-01 available from Toyo Gosei Co., Ltd.). Except for this, the same method and condition as Example 3 were employed, to obtain a light emitting apparatus.

### Comparative Example 1

An adjusting layer was not provided in Example 1. Except for this, the same method and condition as Example 1 were employed, to obtain a light emitting apparatus.

### Comparative Example 2

A plate-like resin layer having a side of 43 mm and a thickness of 25 μm was formed in place of the adjusting layer in Example 1. Except for this, the same method and condition as Example 1 were employed, to obtain a light emitting apparatus.

[Evaluation]

The light emitting apparatuses obtained in Examples and Comparative Examples ware observed. In each of Comparative Examples 1 and 2, the barrier member was broken and the sealing member leaked out. On the other hand, the breakage of the barrier member was not observed in each of Examples 1 to 4.

To evaluate the maximum deformation amount of the barrier member in the thickness direction, the barrier member of the light emitting apparatus obtained in each of Examples 1 to 4 was cut and the resultant cut plane was observed. The evaluation results of the maximum deformation amount when the thickness of the barrier member was defined as 1 were shown in Table 1. As shown in the results, the deformation amount of the barrier member in each of Examples 2 to 4 in which the outer edge surface was formed was less than that in Example 1 in which the outer edge surface was not formed. Among these, in Examples 3 and 4 in which the thickness of the adjusting layer at the outer edge thereof was a half or less of the thickness of the adjusting layer at the center part thereof, the deformation amount of the barrier member 6 was further decreased.

TABLE 1

| | | | Ratio of | | | |
|---|---|---|---|---|---|---|
| | | | thickness | | | |
| | | | of | Ratio of | | |
| | | | adjusting | thickness | | |
| | | | layer at | of | | |
| | | | outer | adjusting | | |
| | | | edge | layer at | | |
| | | | thereof | outer | | |
| | | | to | edge to | Presence | |
| | | | distance | thickness | or | |
| | | | between | of | absence | |
| | | | first | adjusting | of | Maximum |
| | | Material | substrate | layer at | damage | deformation |
| | | of | and | center | of | amount of |
| | | adjusting | second | part | barrier | barrier |
| | Structure | layer | substrate | thereof | member | member |
| Example 1 | FIG. 2A, | Aluminum | 1/2 | 5/8 | Absence | 0.8 |
| | FIG. 2B, | | | | | |
| | and FIG. | | | | | |
| | 2C | | | | | |
| Example 2 | FIG. 1A, | Aluminum | 1/2 | 5/8 | Absence | 0.5 |
| | FIG. 1B, | | | | | |
| | and FIG. | | | | | |
| | 1C | | | | | |
| Example 3 | FIG. 1A, | Aluminum | 3/10 | 3/8 | Absence | 0.4 |
| | FIG. 1B, | | | | | |
| | and FIG. | | | | | |
| | 1C | | | | | |
| Example 4 | FIG. 1A, | Resin | 3/10 | 3/8 | Absence | 0.3 |
| | FIG. 1B, | | | | | |
| | and FIG. | | | | | |
| | 1C | | | | | |
| Comparative | No | — | — | — | Presence | — |
| Example 1 | adjusting | | | | | |
| | layer | | | | | |
| Comparative | Plate-like | Resin | — | — | Presence | — |
| Example 2 | layer is | | | | | |
| | placed in | | | | | |
| | place of | | | | | |
| | adjusting | | | | | |
| | layer | | | | | |

### REFERENCE SIGNS LIST

1a Light emitting apparatus

2a First substrate

3a Second substrate

4a Light emitting element

5a Adjusting layer

6a Barrier member

7a Sealing member

8a Adjusting surface

10a Flat surface (outer edge surface)

1-11. (canceled)

12. A light emitting apparatus comprising:
a first substrate;
a light emitting element supported on a surface of the first substrate;
a second substrate spaced from and facing the surface of the first substrate;
an adjusting layer supported on a surface of the second substrate facing the light emitting element;
a barrier member provided between the first substrate and the second substrate so as to surround the light emitting element and the adjusting layer; and
a sealing member filling a space surrounded by the first substrate, the second substrate, and the barrier member,
the adjusting layer including a surface which faces the first substrate and includes a flat center surface including a center part of the adjusting layer, an adjusting surface formed around the center surface, and a flat outer edge surface closer to an outer edge of the adjusting layer than the adjusting surface is, and
a distance between the adjusting surface and the first substrate becoming greater towards an outer edge of the adjusting layer than at a center part of the adjusting layer.

13. The light emitting apparatus according to claim 12, wherein
the adjusting surface is formed so that a percentage of a distance from an outer edge of the adjusting surface to the barrier member to a distance from the central axis to the barrier member is equal to or less than 50%.

14. The light emitting apparatus according to claim 12, wherein
a thickness of the adjusting layer at the outer edge thereof is a half or less of a thickness of the adjusting layer at the center part thereof.

15. The light emitting apparatus according to claim 12, wherein
the adjusting layer is formed by printing.

16. A lighting apparatus comprising the light emitting apparatus according to claim 12.

17. A method for manufacturing the light emitting apparatus according to claim 12,
the method comprising:
providing the light emitting element and the barrier member on the surface of the first substrate;
providing the adjusting layer on the surface of the second substrate;
disposing the first substrate and the second substrate so that the surface of the first substrate and the surface of the second substrate face each other; and
disposing a sealing member between the light emitting element and the adjusting layer, and spreading the sealing member between the first substrate and the second substrate by pressing the sealing member by the adjusting layer while relatively moving the first substrate close to the second substrate until the barrier member comes into contact with the second substrate.
